(19) United States
(12) Patent Application Publication
(10) Pub. No.: US 2026/0239552 A1
(43) Pub. Date: Aug. 13, 2026

(54) SPRING-LOADED HANDLE DEVICE FOR MULTI-OBJECT CLAMPING IN CLOSED-LOOP COOLING SYSTEM INSTALLATION

(71) Applicant: Aivres Systems Inc., San Jose, CA (US)

(72) Inventor: Yuan-Bo Lan, Taipei (TW)

(21) Appl. No.: 19/049,584

(22) Filed: Feb. 10, 2025

(51) Int. Cl. H05K 7/14; H05K 7/20

(52) U.S. Cl. CPC H05K 7/1415; H05K 7/20254; H05K 7/20263

(57) ABSTRACT

A spring-loaded handle device facilitates the quick and secure installation of closed-loop cooling modules in data centers. A pair of bars on opposite sides of a housing compress a spring, driving first and second rods outward. Plates on the rods separate from corresponding adjustable plates to create clamping gaps for attaching radiator modules, cold plates, or similar components. Releasing the bars allows the spring to retract the rods, closing the gaps and holding the cooling elements firmly in place.

### TECHNICAL FIELD

The present invention relates to clamping devices for data center cooling equipment, specifically spring-loaded handle mechanisms designed to streamline the installation of closed-loop cooling devices.

### BACKGROUND

The efficient and sustainable cooling of data centers is becoming increasingly critical as global demand for digital infrastructure grows. Closed-loop liquid cooling systems (CLLCS) have emerged as a superior solution compared to traditional cooling methods, such as air cooling or open-loop liquid cooling. CLLCS employ a sealed environment where liquid coolant circulates to absorb and dissipate heat from high-performance server components like CPUs and GPUs. This method significantly reduces water and energy consumption, alleviating environmental pressures while ensuring effective heat management in dense server environments.

A typical CLLCS comprises three primary components: a liquid coolant (e.g., distilled water or specialized coolants) that circulates within the closed loop, a water block that transfers heat from server components to the coolant, and a pump with a radiator or heat exchanger to dissipate heat and maintain optimal temperatures. While these systems offer superior thermal efficiency, their modular design presents challenges during installation. Operators must handle separate components such as radiator modules, coolant pipes, and cold plates, requiring precise alignment to prevent damage or operational inefficiency.

As shown in FIG. 1, the current assembly methods rely on screw-based handles pre-installed to cooling modules to facilitate lifting and installation. These handles, however, must be removed post-installation using tools, adding extra time and effort. Additionally, the removal process generates surplus handles, leading to unnecessary material waste and increased costs. Moreover, operators face difficulties in handling and aligning multiple components simultaneously, further complicating the installation process. Addressing these inefficiencies, the present invention introduces a spring-loaded handle device that simplifies the clamping, lifting, and installation of CLLCS components, allowing operators to securely and simultaneously position radiator modules and cold plates without the need for the handles to be removed after installation.

### SUMMARY

In one general aspect, a spring-loaded device may include a housing. The spring-loaded device may also include a pair of bars disposed on opposite sides of a middle section of the housing, each bar being connected to a respective end of a spring located within the housing, at least one of the bars being movable toward the other bar so as to compress the spring. The spring-loaded device may furthermore include a first rod arranged within the housing and operatively coupled to the spring, where pressing the at least one bar toward the other bar causes the spring to compress and displaces the first rod away from a central position within the housing. The spring-loaded device may in addition include a first plate mounted on a remote end of the first rod, the first plate oriented substantially perpendicular to the first rod. The spring-loaded device may moreover include a second plate adjustably mounted relative to the housing, the second plate being arranged in parallel to the first plate. In some embodiments, upon compression of the spring, the first rod displaces the first plate away from the second plate to form a first gap for clamping or releasing a first object.

Other embodiments of this aspect include corresponding computer systems, apparatus, and computer programs recorded on one or more computer storage devices, each configured to perform the actions of the methods.

Implementations may include one or more of the following features.

In some embodiments, both of the pair of bars in the spring-loaded device are symmetrically configured such that pressing either bar individually or both bars together compresses the spring, enabling the first rod to be displaced away from the central position in a controlled manner. In some embodiments, the first rod is slidably received in a guide structure within the housing, thereby ensuring linear travel of the first plate with respect to the second plate during compression and release of the spring.

The spring-loaded device may include a return mechanism that automatically retracts the first rod and the first plate back toward the central position upon release of the at least one bar, thereby moving the first plate closer to the second plate and facilitating clamping action. The spring-loaded device may include: a second rod arranged within the housing on an opposite side of the spring from the first rod, where compressing the spring by pressing the at least one bar simultaneously displaces both the first rod and the second rod away from the central position within the housing.

The spring-loaded device may include: a third plate mounted on a remote end of the second rod, the third plate oriented substantially perpendicular to the second rod; and a fourth plate adjustably mounted relative to the housing, the fourth plate arranged in parallel with the third plate. Upon compression of the spring, the second rod displaces the third plate away from the fourth plate. In some embodiments, the third plate and the fourth plate form a second gap for clamping or releasing a second object, and the first gap and the second gap are created and adjusted simultaneously when the at least one bar is pressed, thereby enabling simultaneous clamping or release of the first object and the second object.

In some embodiments, the first object and the second object may include a radiator module and a cold plate of a closed-loop cooling device. The first gap and the second gap have different sizes. The second plate and the fourth plate are configured for variable positioning relative to the housing, enabling adjustment of a distance between the second plate and the fourth plate. Implementations of the described techniques may include hardware, a method or process, or a computer tangible medium.

In one general aspect, a method may include pressing at least one bar of a pair of bars disposed on opposite sides of a middle section of a housing to compress a spring within the housing. The method may also include displacing a first rod coupled to the spring away from a central position of the housing, thereby moving a first plate mounted on a remote end of the first rod away from a second plate adjustably mounted relative to the housing to form a first gap for clamping or releasing a first object. The method may furthermore include releasing the at least one bar to allow the spring to decompress, thereby retracting the first rod and moving the first plate closer to the second plate to secure the first object. Other embodiments of this aspect include corresponding computer systems, apparatus, and computer programs recorded on one or more computer storage devices, each configured to perform the actions of the methods.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 illustrates an existing assembly device with pre-installed (or pre-attached) handles for installing cooling modules.

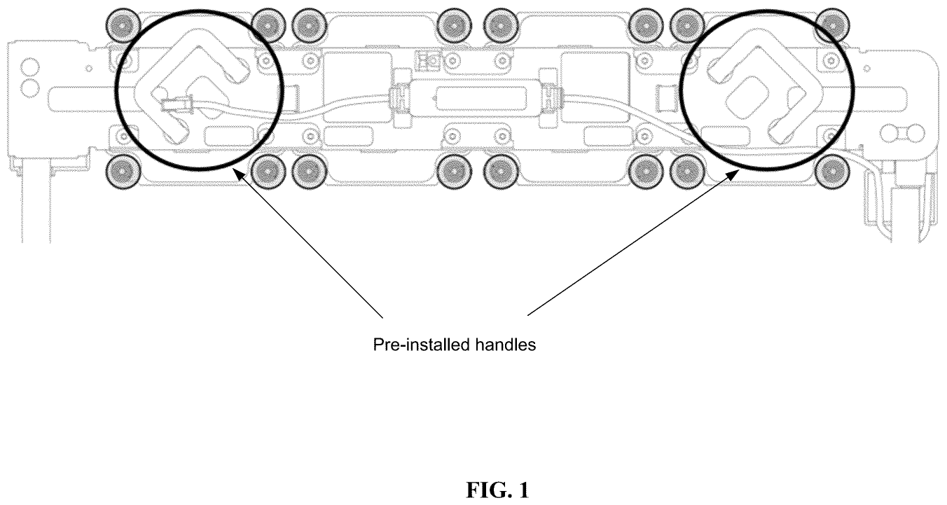

FIG. 2 illustrates an example closed loop liquid cooling system, in accordance with one example embodiment.

FIGS. 3 and 4 illustrate top and side views of an example spring-loaded handle device for installing the closed-loop cooling system, according to one example embodiment.

FIGS. 5 and 6 illustrate top and side views of an example spring-loaded handle device, depicting the device in its compressed state and in its clamping state, in accordance with one embodiment.

FIG. 7 illustrates an example diagram of using the spring-loaded handle device to install the closed-loop cooling system, according to one example embodiment.

FIG. 8 illustrates a process of using the example spring-loaded handle device to install the closed-loop cooling system, according to one example embodiment.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

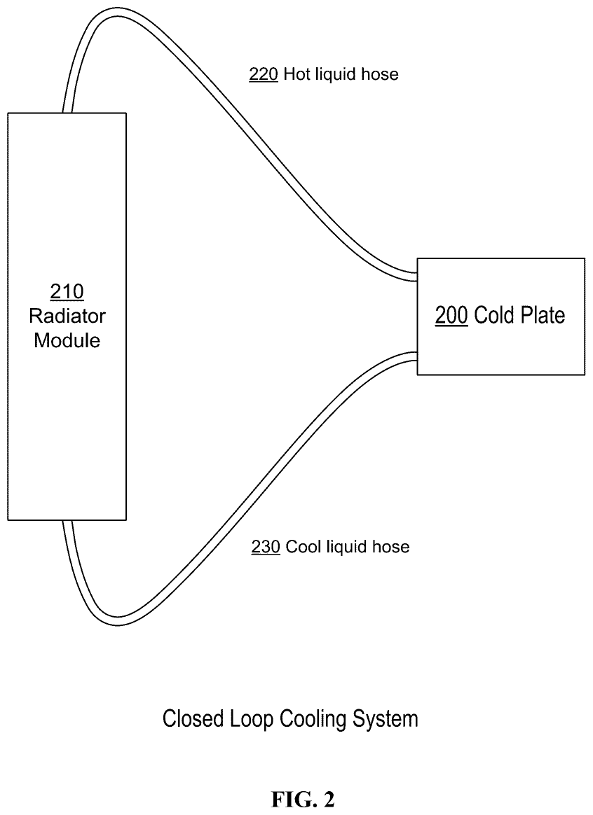

FIG. 2 illustrates an example closed-loop liquid cooling system, in accordance with one example embodiment. As shown, the system includes a cold plate 200, a radiator module 210, a hot liquid hose 220, and a cold liquid hose 230. The cold plate 200 is designed to be affixed directly onto a heat-generating component, such as a CPU or GPU, to absorb thermal energy. The radiator module 210 dissipates that heat by transferring it from the liquid coolant to the surrounding air or another cooling medium. Hot liquid flows from the cold plate 200 through the hot liquid hose 220 into the radiator module 210, where it is cooled, and the cooled liquid returns to the cold plate 200 via the cold liquid hose 230, ensuring continuous circulation of the coolant.

In current closed-loop cooling module designs, these components—radiator modules, coolant pipes, and cold plates—are separate and must be handled and installed individually. This modularity presents challenges for operators during installation, as they must simultaneously manage multiple parts with precision to ensure proper alignment and secure placement. Existing solutions often rely on screw-based handles pre-installed on each module to facilitate handling. However, these handles introduce additional inefficiencies: (1) they require pre-installation on each module, adding to preparation time; (2) they must be removed post-installation, requiring tools and increasing assembly time; and (3) their removal generates surplus parts, contributing to unnecessary material waste and costs.

This design complexity underscores the need for an improved clamping and handling mechanism, such as the spring-loaded handle device described in subsequent figures, which simplifies the process by enabling operators to simultaneously handle and install these components efficiently, without requiring separate fasteners or generating surplus material.

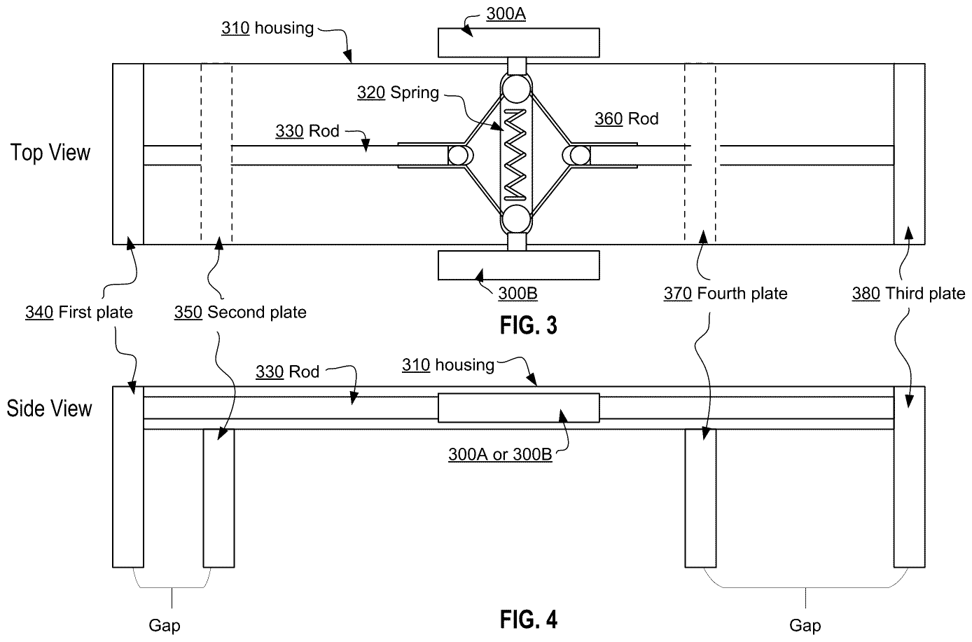

FIGS. 3 and 4 illustrate top and side views of an example spring-loaded handle device for installing the closed-loop cooling system, according to one example embodiment. The device comprises a housing 310, a pair of bars 300A and 300B, a spring 320, a rod 330, a first plate 340, and a second plate 350. Here, the term “plates” refer to grippers or paddles that grasp or clamp with friction. These components are configured to work together to facilitate efficient clamping or release of objects, providing a streamlined and tool-free operation.

The housing 310 serves as the central structure for the device, enclosing and supporting the internal components. The pair of bars 300A and 300B are symmetrically disposed on opposite sides of a middle section of the housing. Each bar is connected to a respective end of the spring 320 located within the housing. At least one of the bars, and optionally both, can be pressed toward the other, compressing the spring 320. This compression initiates the movement of the internal components.

The spring 320 is operatively coupled to the rod 330, which is arranged within the housing. When the spring 320 is compressed, the rod 330 is displaced away from the central position of the housing, moving linearly along a guide structure. The guide structure ensures that the rod travels in a controlled and linear fashion, preventing misalignment during operation. The first plate 340 is mounted on the remote end of the rod 330, oriented substantially perpendicular to the rod 330 (from both the top view in FIG. 3 and the side view in FIG. 4).

A second plate 350, adjustably mounted relative to the housing, is arranged in parallel with the first plate. When the spring 320 is compressed by pressing the bars, the rod 330 moves the first plate 340 away from the second plate 350, forming a first gap for clamping or releasing a first object. Upon releasing the bars, a return mechanism automatically retracts the rod 330 and the first plate 340 back toward the central position. This retraction closes the gap, facilitating secure clamping of the object between the first and second plates.

The symmetrical configuration of the pair of bars 300A and 300B allows the user to compress the spring by pressing either bar individually or both bars simultaneously, offering flexibility in operation. This design ensures that the rod 330 and the first plate 340 move in a controlled manner regardless of the direction of force applied. The return mechanism integrated into the device streamlines the operation by eliminating the need for manual resetting, ensuring that the device is always ready for the next use.

In some embodiments and as shown in FIGS. 3 and 4, the spring-loaded handle device also includes a second rod 360 arranged within the housing 310, positioned on the opposite side of the spring 320 from the first rod 330. This second rod 360 is operatively coupled to the spring 320 such that when the spring 320 is compressed by pressing one or both of the bars 300A and 300B, both the first rod 330 and the second rod 360 are simultaneously displaced away from the central position within the housing 310.

At the remote end of the second rod 360, a third plate 380 is mounted, oriented substantially perpendicular to the second rod (from both the top view in FIG. 3 and the side view in FIG. 4). Similar to the first plate 340, this third plate 380 moves linearly in response to the displacement of the second rod 360. A fourth plate 370 is adjustably mounted relative to the housing, arranged in parallel with the third plate 380. When the spring is compressed, the second rod 360 moves the third plate away from the fourth plate 370, forming a second gap. This second gap operates in conjunction with the first gap formed between the first plate 340 and the second plate 350, allowing the device to simultaneously clamp or release two separate objects.

The first gap and the second gap are created and adjusted simultaneously when the bars 300A and 300B are pressed. This design enables the device to handle two objects at once, streamlining installation or assembly processes. For example, the first object and second object can include the radiator module and the cold plate of the closed-loop cooling system illustrated in FIG. 2, both of which can be clamped securely and efficiently in a single operation. The synchronized movement of the first and second rods ensures that both modules are aligned and held firmly without requiring additional adjustments.

The device may further allow for independent customization of the first and second gaps. The second plate and the fourth plate are configured for variable positioning relative to the housing, enabling the operator to adjust the distance between these plates. This feature accommodates objects of varying sizes or shapes, ensuring flexibility in application. Additionally, the first gap and the second gap can be set to different sizes, allowing the device to securely clamp objects with dissimilar dimensions while maintaining stability and precision.

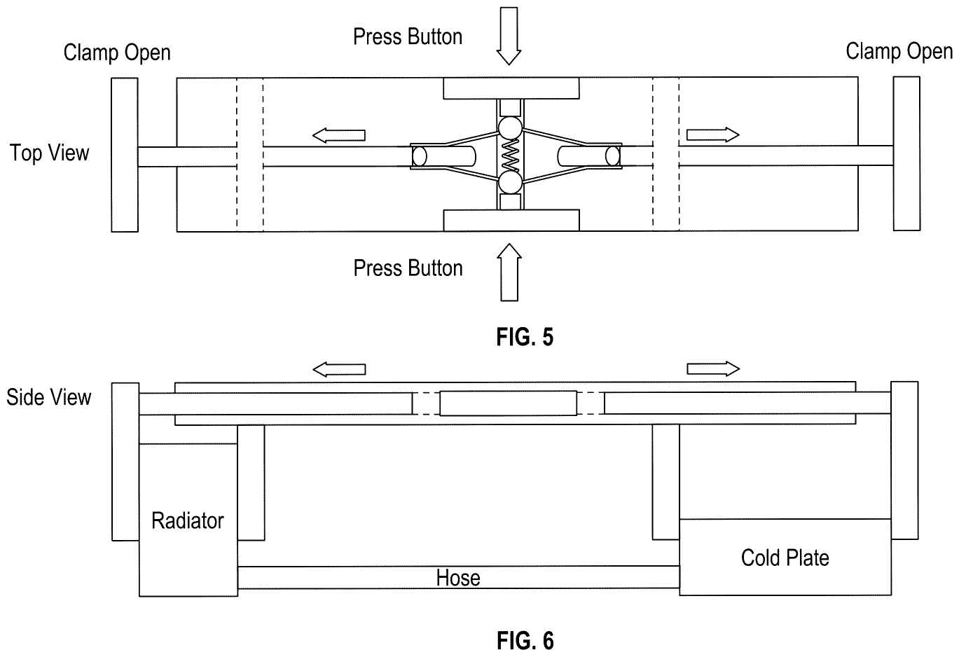

FIGS. 5 and 6 illustrate top and side views of an example spring-loaded handle device, depicting the device in its compressed state and in its clamping state, in accordance with one embodiment.

The top view in FIG. 5 shows that when the buttons (i.e., the bars) in the middle section of the housing are pressed, the spring inside the housing compresses. This compression causes the rods on both sides of the spring to move outward, away from the middle section of the housing. The outward movement of the rods pushes the clamps on each end of the housing open, creating gaps for placing the objects to be clamped. This action enables the user to secure the cold plate and radiator module into the clamps quickly and efficiently without the need for separate fasteners.

The side view in FIG. 6 illustrates that the two clamps may be configured with different gap sizes, facilitating the clamping of objects with different widths. For example, in practical applications, the cold plate and the radiator module of a closed-loop cooling system often vary in size. To accommodate this, the plates that are not pushed away by the rods (referred to as the fixed plates) may be adjustably mounted relative to the housing. These plates are configured for variable positioning relative to the housing, enabling precise adjustment of the gap sizes of the clamps.

In one specific implementation, the variable positioning of the fixed plates relative to the housing is accomplished using an adjustable mounting mechanism. This mechanism may include a series of slots or grooves on the housing, along with corresponding fasteners such as pins that allow the fixed plates to be repositioned along the grooves. By loosening the fasteners, the operator can slide the fixed plates to the desired position, adjust the gap size for each clamp, and then secure the plates in place by tightening the fasteners. In other embodiments, the adjustable mounting may utilize a ratcheting mechanism or a set of detents that allow the fixed plates to lock into predefined positions, offering a tool-free adjustment option.

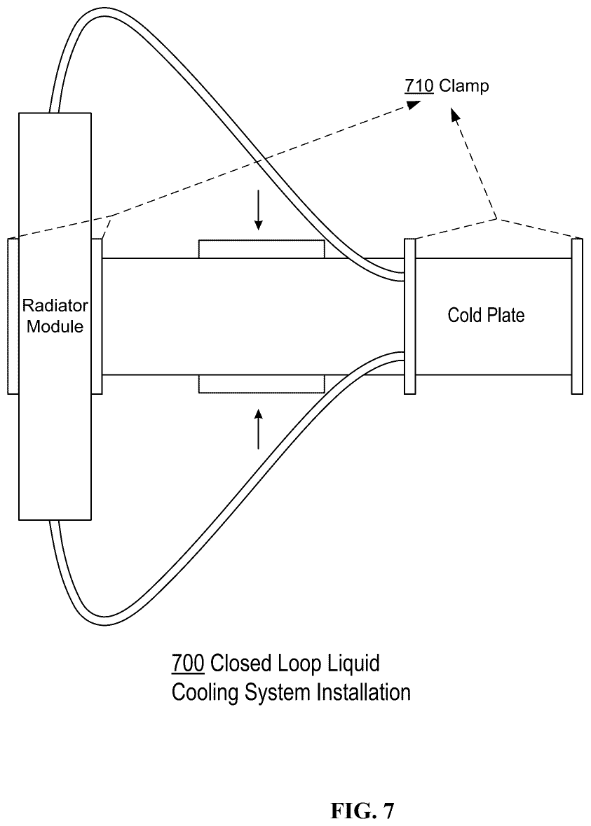

FIG. 7 illustrates an example diagram of using the spring-loaded handle device to install the components of a closed-loop cooling system 700, according to one example embodiment. FIG. 7 demonstrates how the spring-loaded handle device operates to securely hold and align both the cold plate and the liquid-cooling radiator module, facilitating their simultaneous installation onto a server or other assembly.

As shown in FIG. 7, the spring-loaded handle device features two clamps 710 formed by plates located on opposite ends of the device's housing. The cold plate and the radiator module are positioned between these clamps 710. When a user presses the pair of bars in the middle section of the housing, the internal spring compresses. This compression generates force that pushes two rods away from the central position within the housing. The rods, in turn, drive the plates mounted at their remote ends outward, creating gaps that form the clamps 710. These clamps 710 are designed to securely hold the cold plate and the radiator module during the installation process.

When the user releases the pair of bars, the spring expands and forces the rods to retract back toward the central position of the housing. This retraction causes the plates to move inward, tightening the clamps 710 and securely holding the cold plate and the radiator module in place. The spring's action ensures a consistent and firm grip on the components without requiring additional fasteners or manual adjustments.

The spring-loaded handle device allows for the simultaneous handling and clamping 710 of both components, eliminating the need for screw-based handles that require pre-installation and subsequent removal. Once the installation is complete, the user can press the bars again to release the clamps 710, allowing the device to be removed quickly and easily. This reusable and efficient design reduces installation time, minimizes material waste, and ensures repeatable performance for installing multiple systems.

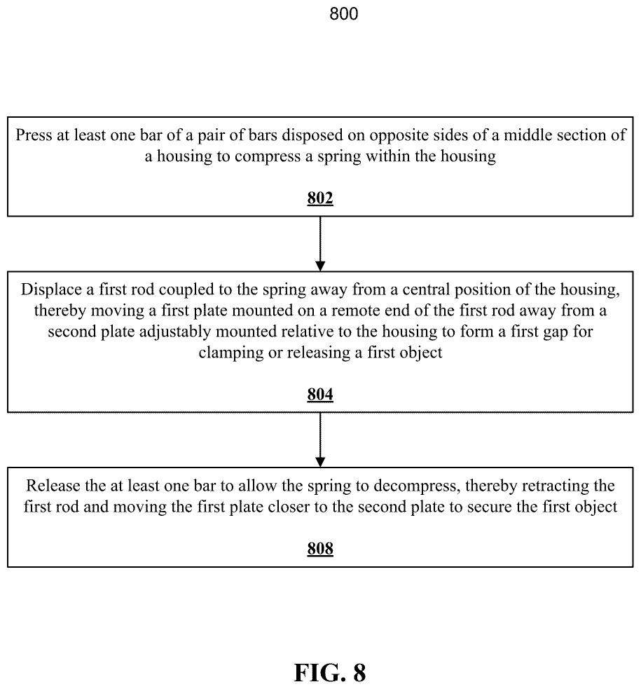

FIG. 8 illustrates a process of using the example spring-loaded handle device to install the closed-loop cooling system, according to one example embodiment. In some implementations, one or more process blocks of FIG. 8 may be performed by a device.

As shown in FIG. 8, process 800 may include pressing at least one bar of a pair of bars disposed on opposite sides of a middle section of a housing to compress a spring within the housing (block 802). For example, a device may press at least one bar of a pair of bars disposed on opposite sides of a middle section of a housing to compress a spring within the housing, as described above.

As also shown in FIG. 8, process 800 may include displacing a first rod coupled to the spring away from a central position of the housing, thereby moving a first plate mounted on a remote end of the first rod away from a second plate adjustably mounted relative to the housing to form a first gap for clamping or releasing a first object (block 804). For example, a device may displace a first rod coupled to the spring away from a central position of the housing, thereby moving a first plate mounted on a remote end of the first rod away from a second plate adjustably mounted relative to the housing to form a first gap for clamping or releasing a first object, as described above.

As further shown in FIG. 8, process 800 may include releasing the at least one bar to allow the spring to decompress, thereby retracting the first rod and moving the first plate closer to the second plate to secure the first object (block 808). For example, a device may release the at least one bar to allow the spring to decompress, thereby retracting the first rod and moving the first plate closer to the second plate to secure the first object, as described above.

Process 800 may include additional implementations, such as any single implementation or any combination of implementations described below and/or in connection with one or more other processes described elsewhere herein. In a first implementation, process 800 may include pressing both bars of the pair of bars simultaneously to symmetrically compress the spring, enabling controlled displacement of the first rod and the first plate away from the central position.

In a second implementation, alone or in combination with the first implementation, displacing the first rod includes sliding the first rod within a guide structure inside the housing to ensure linear travel of the first plate with respect to the second plate during compression and release of the spring.

In a third implementation, alone or in combination with the first and second implementations, process 800 further includes activating a return mechanism to retract the first rod and the first plate back toward the central position upon releasing the at least one bar, thereby facilitating clamping of the first object between the first plate and the second plate.

In a fourth implementation, alone or in combination with one or more of the first through third implementations, process 800 further includes displacing a second rod located on an opposite side of the spring from the first rod away from the central position of the housing simultaneously with the displacement of the first rod.

In a fifth implementation, alone or in combination with one or more of the first through fourth implementations, process 800 further includes displacing a third plate mounted on a remote end of the second rod away from a fourth plate adjustably mounted relative to the housing to form a second gap for clamping a second object; and releasing the at least one bar to allow the spring to move the third plate toward the fourth plate, thereby clamping the second object.

In a sixth implementation, alone or in combination with one or more of the first through fifth implementations, the first gap and the second gap are formed and adjusted simultaneously when the at least one bar is pressed, thereby enabling clamping or release of the first object and the second object at the same time.

In a seventh implementation, alone or in combination with one or more of the first through sixth implementations, the first object and the second object may include a radiator module and a cold plate of a closed-loop cooling system, respectively, and the method includes clamping both the radiator module and the cold plate simultaneously for secure installation.

In an eighth implementation, alone or in combination with one or more of the first through seventh implementations, adjusting the first gap and the second gap may include configuring the second plate and the fourth plate for variable positioning relative to the housing.

In a ninth implementation, alone or in combination with one or more of the first through eighth implementations, the first gap and the second gap are adjusted to different sizes by selectively varying the position of the second plate and the fourth plate relative to the housing, enabling independent clamping of the first object and the second object.

Although FIG. 8 shows example blocks of process 800, in some implementations, process 800 may include additional blocks, fewer blocks, different blocks, or differently arranged blocks than those depicted in FIG. 8. Additionally, or alternatively, two or more of the blocks of process 800 may be performed in parallel.

The foregoing description of the present disclosure has been provided for the purposes of illustration and description. It is not intended to be exhaustive or to limit the disclosure to the precise forms disclosed. The breadth and scope of the present disclosure should not be limited by any of the above-described exemplary embodiments. Many modifications and variations will be apparent to the practitioner skilled in the art. The modifications and variations include any relevant combination of the disclosed features. The embodiments were chosen and described in order to best explain the principles of the disclosure and its practical application, thereby enabling others skilled in the art to understand the disclosure for various embodiments and with various modifications that are suited to the particular use contemplated. It is intended that the scope of the disclosure be defined by the following claims and their equivalence.

What is claimed is:

1. A spring-loaded handle device, comprising:
a housing;
a pair of bars disposed on opposite sides of a middle section of the housing, each bar being connected to a respective end of a spring located within the housing, at least one of the bars being movable toward the other bar to compress the spring;
a first rod arranged within the housing and operatively coupled to the spring, wherein pressing the at least one bar causes the spring to compress and displaces the first rod away from a central position within the housing;
a first plate mounted on a remote end of the first rod, the first plate oriented substantially perpendicular to the first rod; and
a second plate adjustably mounted relative to the housing, the second plate being arranged in parallel to the first plate,
wherein, upon compression of the spring, the first rod displaces the first plate away from the second plate to form a first gap for clamping or releasing a first object.

2. The spring-loaded handle device of claim 1, wherein both of the pair of bars are symmetrically configured such that pressing either bar individually or both bars together compresses the spring, enabling the first rod to be displaced away from the central position in a controlled manner.

3. The spring-loaded handle device of claim 1, wherein the first rod is slidably received in a guide structure within the housing, thereby ensuring linear travel of the first plate with respect to the second plate during compression and release of the spring.

4. The spring-loaded handle device of claim 1, further comprising a return mechanism that automatically retracts the first rod and the first plate back toward the central position upon release of the at least one bar, thereby moving the first plate closer to the second plate and facilitating clamping action.

5. The spring-loaded handle device of claim 1, further comprising:
a second rod arranged within the housing on an opposite side of the spring from the first rod, wherein compressing the spring by pressing the at least one bar simultaneously displaces both the first rod and the second rod away from the central position within the housing.

6. The spring-loaded handle device of claim 5, further comprising:
a third plate mounted on a remote end of the second rod, the third plate oriented substantially perpendicular to the second rod; and
a fourth plate adjustably mounted relative to the housing, the fourth plate arranged in parallel with the third plate,
wherein, upon compression of the spring, the second rod displaces the third plate away from the fourth plate.

7. The spring-loaded handle device of claim 6, wherein:
the third plate and the fourth plate form a second gap for clamping or releasing a second object, and
the first gap and the second gap are created and adjusted simultaneously when the at least one bar is pressed, thereby enabling simultaneous clamping or release of the first object and the second object.

8. The spring-loaded handle device of claim 7, wherein the first object and the second object comprise a radiator module and a cold plate of a closed-loop cooling device.

9. The spring-loaded handle device of claim 7, wherein the first gap and the second gap have different sizes.

10. The spring-loaded handle device of claim 7, wherein the second plate and the fourth plate are configured for variable positioning relative to the housing, enabling adjustment of a distance between the second plate and the fourth plate.

11. A method for clamping or releasing objects using a spring-loaded handle device, the method comprising:
pressing at least one bar of a pair of bars disposed on opposite sides of a middle section of a housing to compress a spring within the housing;
displacing a first rod coupled to the spring away from a central position of the housing, thereby moving a first plate mounted on a remote end of the first rod away from a second plate adjustably mounted relative to the housing to form a first gap for clamping or releasing a first object; and
releasing the at least one bar to allow the spring to decompress, thereby retracting the first rod and moving the first plate closer to the second plate to secure the first object.

12. The method of claim 11, further comprising pressing both bars of the pair of bars simultaneously to symmetrically compress the spring, enabling controlled displacement of the first rod and the first plate away from the central position.

13. The method of claim 11, wherein the displacing the first rod includes sliding the first rod within a guide structure inside the housing to ensure linear travel of the first plate with respect to the second plate during compression and release of the spring.

14. The method of claim 11, further comprising:
activating a return mechanism to retract the first rod and the first plate back toward the central position upon releasing the at least one bar, thereby facilitating clamping of the first object between the first plate and the second plate.

15. The method of claim 11, further comprising:
displacing a second rod located on an opposite side of the spring from the first rod away from the central position of the housing simultaneously with the displacement of the first rod.

16. The method of claim 15, further comprising:
displacing a third plate mounted on a remote end of the second rod away from a fourth plate adjustably mounted relative to the housing to form a second gap for clamping a second object; and
releasing the at least one bar to allow the spring to move the third plate toward the fourth plate, thereby clamping the second object.

17. The method of claim 16, wherein the first gap and the second gap are formed and adjusted simultaneously when the at least one bar is pressed, thereby enabling clamping or release of the first object and the second object at the same time.

18. The method of claim 17, wherein the first object and the second object comprise a radiator module and a cold plate of a closed-loop cooling system, respectively, and the method includes clamping both the radiator module and the cold plate simultaneously for secure installation.

19. The method of claim 17, wherein the adjusting the first gap and the second gap comprises configuring the second plate and the fourth plate for variable positioning relative to the housing.

20. The method of claim 17, wherein the first gap and the second gap are adjusted to different sizes by selectively varying the position of the second plate and the fourth plate relative to the housing, enabling independent clamping of the first object and the second object.
